(19) United States
(12) Patent Application Publication
(10) Pub. No.: US 2007/0111477 A1
(43) Pub. Date: May 17, 2007

(54) Semiconductor wafer

(75) Inventors: Yumi Maruyama, Kariya-city (JP); Tetsuo Fujii, Toyohashi-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/600,099

(22) Filed: Nov. 16, 2006

(30) Foreign Application Priority Data
Nov. 16, 2005 (JP) 2005-331217
Sep. 1, 2006 (JP) 2006-237632

(51) Int. Cl. H01L 21/00; H01L 23/544

(52) U.S. Cl. 438/460; 257/797

(57) ABSTRACT

A semiconductor wafer is disclosed for which irradiation of a laser beam forms a modified region due to multiphoton absorption to thereby facilitate dicing of the semiconductor wafer. The semiconductor wafer includes a formation member and a scribe groove located on the formation member according to an irradiation position of the laser beam. The scribe groove defines an open end and a bottom end. A width of the scribe groove is greater at the open end than at the bottom end.

### CROSS REFERENCE TO RELATED APPLICATIONS

The following is based on and claims the benefit of Japanese Patent Application No. 2005-331217, filed Nov. 16, 2005 and Japanese Patent Application No. 2006-237632, filed Sep. 1, 2006, each of which are incorporated herein by reference.

### FIELD

This invention relates to a semiconductor wafer and, more particularly relates to a semiconductor wafer in which irradiation of a laser beam forms a modified region by multiphoton absorption for dicing.

### BACKGROUND

Various methods have been proposed for dicing a semiconductor wafer. For instance, Japanese Patent Publication No. 2003-338468A discloses a method of dicing a wafer starting from a modified region formed by multiphoton absorption. The multiphoton absorption is caused by irradiation of a laser beam in the interior of the wafer.

For instance, as illustrated in FIG. 10, a scribe groove 125 (i.e., trench) is formed for the wafer 120 along a predetermined dicing line DL, and a bottom 125b (i.e., bottom surface) of the scribe groove 125 is specified as an entrance surface of laser beams L1, L2 (i.e., a surface onto which the laser beams are irradiated).

More specifically, in the case where the wafer 120 has a multilayer structure of an SOI (Silicon On Insulator) constructed with a lamination of a semiconductor substrate 121, an embedded layer of an oxide 122 (BOX; Buried OXide), and a single-crystal silicon layer 123, or the like, the refractive index to the laser beam differs depending on thickness and material of each layer due to differences in optical properties of each layer. For this reason, a laser beam is likely to reflect or scatter in a boundary surface of layers of different refractive indices, etc. (e.g., a boundary surface between the embedded oxide layer 122 and the single-crystal silicon layer 123). Accordingly, the scribe groove 125 is formed along the predetermined dicing line DL in the case of the wafer 120. Since a part of the single-crystal silicon layer 123 is removed, it becomes possible to form focal points P1, P2 of the laser beams L1, L2 along an optical axis J at either a shallow position (i.e., a position near the surface 120a) of the semiconductor substrate 121 or a deep position (i.e., a position near the opposite side 120b).

The scribe groove 125 is set to have the same width in a direction perpendicular to the predetermined dicing line DL. Accordingly, a wall 125c that joins the opening 125a to the bottom 125b is provided approximately at a right angle (i.e., θa=90°) with respect to the outer surface 120a and the bottom 125b. For this reason, if the chips diced by the laser (i.e., semiconductor chips) rub against each other, an angle part 120c that forms the opening 125a of the scribe groove 125 can chip off, resulting in degradation in quality of the chips.

### SUMMARY

A semiconductor wafer is disclosed for which irradiation of a laser beam forms a modified region due to multiphoton absorption to thereby facilitate dicing of the semiconductor wafer. The semiconductor wafer includes a formation member with an outer surface. The semiconductor wafer also includes a scribe groove located on the formation member according to an irradiation position of the laser beam. The scribe groove includes a side wall that is planar and that is provided at a tilt angle with respect to the outer surface of the formation member. The tilt angle is the smallest angle between the side wall and the outer surface, and the tilt angle is between ninety degrees (90°) and one hundred eighty degrees (180°).

Furthermore, a semiconductor wafer is disclosed for which irradiation of a laser beam forms a modified region due to multiphoton absorption to thereby facilitate dicing of the semiconductor wafer. The semiconductor wafer includes a formation member with an outer surface and a scribe groove located on the formation member according to an irradiation position of the laser beam. The scribe groove includes a side wall that is curved such that a tangent angle is defined between a tangent line of the side wall and the outer surface of the formation member. The tangent angle is the smallest angle between the tangent line and the outer surface, and the tangent angle is between ninety degrees (90°) and one hundred eighty degrees (180°).

Moreover, a semiconductor wafer is disclosed for which irradiation of a laser beam forms a modified region due to multiphoton absorption to thereby facilitate dicing of the semiconductor wafer. The semiconductor wafer includes a formation member and a scribe groove located on the formation member according to an irradiation position of the laser beam. The scribe groove defines an open end and a bottom end. A width of the scribe groove is greater at the open end than at the bottom end.

### BRIEF DESCRIPTION OF THE DRAWINGS

FIG. 1 is a perspective view of one embodiment of a semiconductor wafer;

FIGS. 2A and 2B are sectional views of the semiconductor wafer of FIG. 1 shown during manufacturing;

FIG. 3A is a sectional view of the semiconductor wafer of FIG. 1 and FIG. 3B is a sectional view of another embodiment of the semiconductor wafer of FIG. 1;

FIGS. 4A and 4B are sectional views of other embodiments of the semiconductor wafer of FIG. 1;

FIGS. 5A and 5B are sectional views of other embodiments of the semiconductor wafer of FIG. 1;

FIGS. 6A, 6B, and 6C are sectional views of other embodiments of the semiconductor wafer of FIG. 1;

FIGS. 7A, 7B, and 7C are sectional views of other embodiments of the semiconductor wafer of FIG. 1;

FIGS. 8A, 8B, and 8C are sectional views of other embodiments of the semiconductor wafer of FIG. 1;

FIGS. 9A, 9B, and 9C are sectional views of other embodiments of the semiconductor wafer of FIG. 1; and

FIG. 10 is a perspective view of a semiconductor wafer of the prior art.

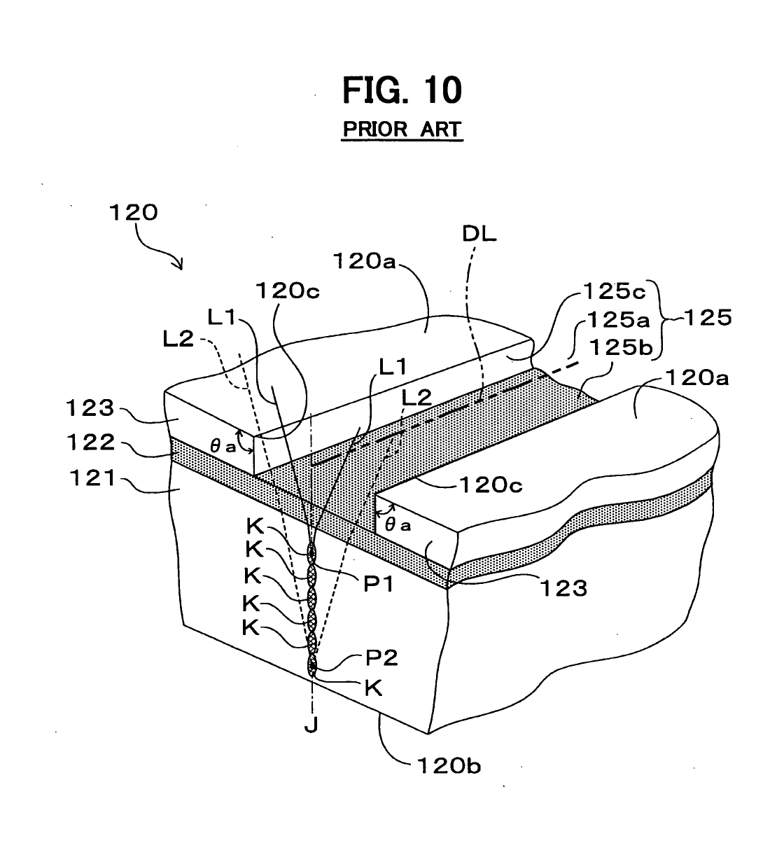

### DETAILED DESCRIPTION OF THE PREFERRED EMBODIMENTS

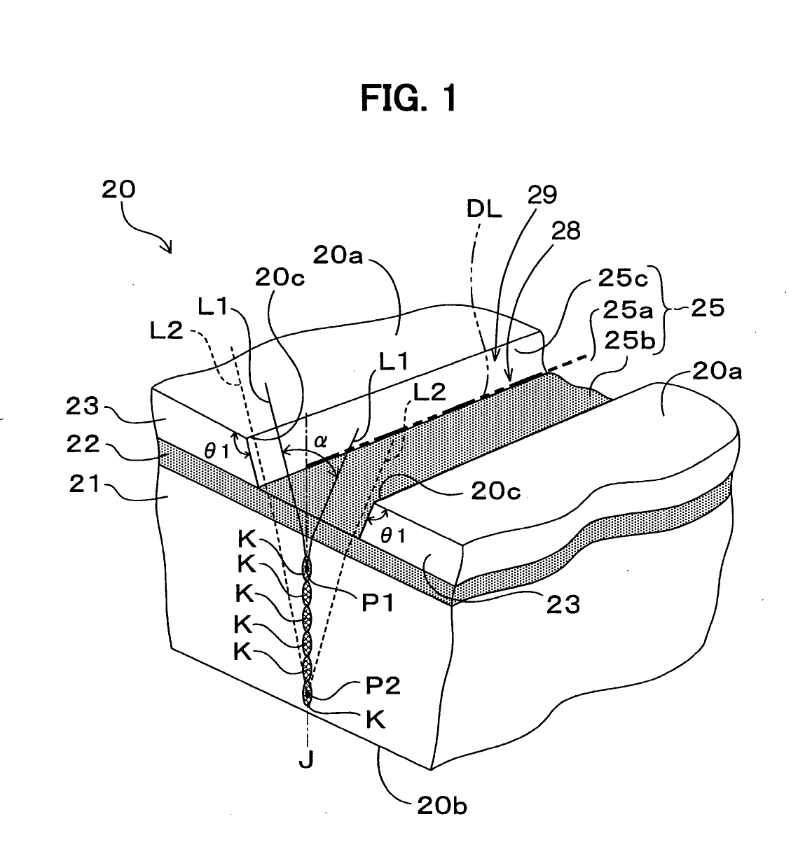

Referring initially to FIGS. 1 through 4B, one embodiment of a semiconductor wafer 20 is illustrated. As shown in FIG. 1, the wafer 20 is a multilayer substrate having an SOI structure constructed with a semiconductor substrate 21 (Si), an embedded oxide layer 22 (BOX), a single-crystal silicon layer 23 laminated from the bottom side to the top side and has a substantially thin disc shape.

Although not illustrated in this wafer 20, a plurality of chips formed through a diffusion process and the like are aligned and arranged in rows and columns. A dicing line DL is illustrated in a predetermined location along which the chips are diced away from the wafer by laser dicing. Also, expand tape (not shown) is glued to substantially all of a reverse side 20b of the wafer 20. It will be appreciated that the dicing line DL is a virtual line (i.e., a line does not exist actually on an outer surface 20a of the wafer 20).

The irradiation of laser beams L1, L2 onto the predetermined dicing line DL makes it possible to form a modified region K by multiphoton absorption in the interior of the semiconductor substrate 21. The wafer 20 can be separated into a plurality of chips by being diced starting from this modified region K. More specifically, dicing occurs starting at the modified regions K via a tension force. The tension force is generated, for example, by pulling the expand tape on the reverse side 20b toward an outer radial direction of the wafer and pressurizing the wafer 20 from the reverse side 20b.

Thus, the laser beams L1, L2 are irradiated along the predetermined dicing line DL and the modified region K is formed in the interior of the wafer when the dicing is performed. The laser beams L1, L2 are focused according to a convergence angle α. More specifically, the convergence angle α is the angle of the condenser lens for focusing the laser beams L1, L2.

The wafer 20 is multilayered by an SOI structure, and each layer can have a different refractive index for the laser beams L1, L2 depending on its thickness and material. As such, the laser beam can generate reflection and scattering at a boundary surface between, for example, the embedded oxide layer 22 and the single-crystal silicon layer 23. Therefore, the wafer 20 of this embodiment is provided with a scribe groove 25 therein. The scribe groove 25 is provided in a formation member of the wafer 20. In the embodiment shown, the formation member is the single-crystal silicon layer 23; however, it will be appreciated that the scribe groove 25 could be any suitable formation member other than the single-crystal layer 23. In the embodiment shown, the scribe groove 25 is formed by removing a portion of the single-crystal silicon layer 23 on the predetermined dicing line DL, which could otherwise hinder the laser beams L1, L2 from forming focal points P1, P2.

The scribe groove 25 is a linear groove with an axis extending along the predetermined dicing line DL. The depth of the scribe groove 25 extends from the outer surface 20a toward the embedded oxide layer 22 so as to define two side walls 25c extending between the outer surface 20a and the embedded oxide layer 22. The two side walls 25c are separated at a distance across the width of the scribe groove 25. It is understood that the embedded oxide layer 22 is the bottom surface 25b of the scribe groove 25. In the depth direction, a bottom end 28 of the scribe groove 25 reaches the embedded oxide layer 22, and an open end 29 of the scribe groove 25 is adjacent the surface 20a. The width of the scribe groove 25 extends perpendicular to the dicing line DL.

The scribe groove 25 has a cross-sectional trapezoidal shape closing toward the embedded oxide layer 22. In other words, the width of the scribe groove 25 at the bottom end 28 is less than the width of the scribe groove 25 at the open end 29. Furthermore, the walls 25c are substantially planar. Also, the walls 25c are provided at an obtuse angle θ1 (90°<θ1<180°) with respect to the outer surface 20a of the wafer 20. In other words, the angle θ1 is the smallest angle between the respective wall 25c and the outer surface 20a, and yet the angle θ1 is an obtuse angle.

In one embodiment, the scribe groove 25 is formed, for example, by chemical processing, such as wet etching and dry etching, or by mechanical processing, such as cutting with a dicing blade etc. and irradiation of a laser beam. Moreover, the bottom surface 25b of the scribe groove 25 is substantially flat and smooth to thereby suppress reflection and scattering of the laser beams L1, L2.

As such, an angle part 20c at an obtuse angle is defined by the wall 25c and the surface 20a on the predetermined dicing line DL. Since the angle part that forms the scribe groove 25 of the chip obtained by dicing it from the wafer 20 ultimately has an obtuse angle, the angle part is resistant to chipping as compared with the prior art where the angle part is at a right angle or an acute angle.

The wall 25c of the scribe groove 25 is formed so as to form a flat slope having a tilt angle θ1. In one embodiment, the tilt angle θ1 equals approximately half of the convergence angle a plus ninety degrees (as viewed on a plane). That is:
θ1=α/2+90°
Thus, the wall surface of a wall 25c can be made almost parallel to fringe contour lines of the laser beams L1, L2 focused by the condenser lens. As such, even if the condenser lens is brought close to the surface 20a of the wafer 20, it is possible to form the focal point P2 at a deep position of the semiconductor substrate 21 while the single-crystal silicon layer 23 does not interrupt propagation of the focused laser beam L2.

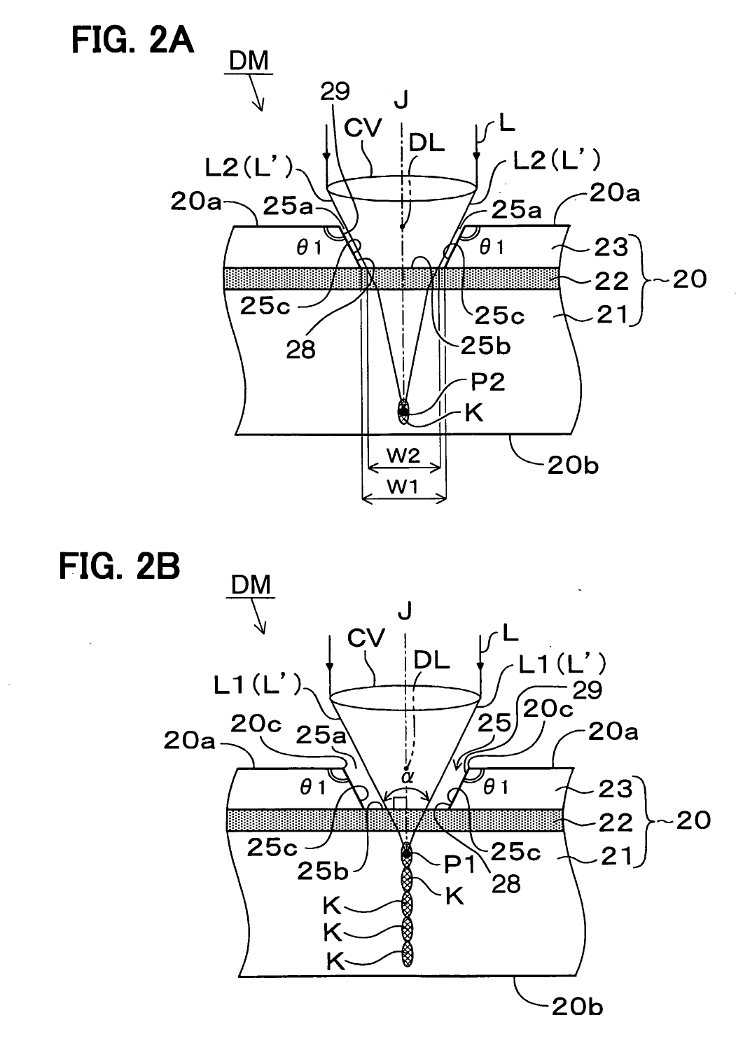

In the wafer 20 according to this embodiment, it becomes possible for a dicing machine DM (FIG. 2) to form a modified region K by forming the scribe groove 25 on the surface 20a along the predetermined dicing line DL. The dicing machine DM consists of an laser light source (not shown) capable of generating a laser beam, a condenser lens CV capable of focussing the laser beam from this laser light source at a predetermined focal length, a translation mechanism (not shown) capable of translating the condenser lens CV vertically along an optical axis J of the laser beam, an table (not shown) capable of placing and holding the wafer 20, etc.

As shown in FIG. 2A, the condenser lens CV is provided adjacent the surface 20a of the wafer 20 and is so positioned that the optical axis J of the laser beam L2 focused by the condenser lens CV passes the predetermined dicing line DL of the wafer 20 and becomes approximately perpendicular to the bottom 25b of the scribe groove 25. The distance between the condenser lens CV and the bottom 25b is a predetermined value. As such, the tilt angle θ1 is set in such a way that the laser beam L2 focused by the condenser lens CV is focused (i.e., converged) at a position further than a predetermined focal length by as much as it is refracted at a boundary surface between the embedded oxide layer 22 and the semiconductor substrate 21. Also, a fringe contour line L′ of the laser beam L2 focused by the condenser lens CV is made approximately parallel to the wall surface of the wall 25c of the scribe groove 25. Therefore, the focal point P2 can be formed, for example, at a deep position (i.e., adjacent the reverse side 20b) in the semiconductor substrate 21 of the wafer 20.

Because of formation of the scribe groove 25, the laser beam L2 is irradiated onto the bottom 25b of the scribe groove 25 as an entrance plane and not onto the single-crystal silicon layer 23 as an entrance plane. Thus, reflection and scattering of the laser beam L2 can be better controlled and it becomes possible to form the focal point P2 at a predetermined deep position of the semiconductor substrate 21 and form a modified region at this deep position.

Furthermore, as shown in FIG. 2B, the laser beam L1 focused by the condenser lens CV is focused (converged) at a predetermined focal length by disposing it away from the surface 20a of the wafer 20, and for example, the focal point P1 is formed at a shallow position in the semiconductor substrate 21 (i.e., a position adjacent the surface 20a).

Since the scribe groove 25 is formed and the single-crystal layer in the surface 20a is removed, the laser beam L1 is irradiated onto the bottom 25b of the scribe groove 25 as an entrance plane and not onto the single-crystal silicon layer 23 as an entrance plane, there is no boundary surface between the single-crystal silicon layer 23 and the embedded oxide layer 22 in a region where the laser beam L1 is irradiated. Therefore, reflection and scattering of the laser beam L1 at the boundary surface can be better controlled. A focal point is located at a predetermined shallow position of the semiconductor substrate 21 (i.e., adjacent the surface 20a) and the modified region K is formed.

It is noted that, in the boundary surface between the scribe groove 25 (i.e., air) and the embedded oxide layer 22, there is substantially zero refraction of the laser beams L1, L2. Accordingly, the laser beams L1, L2 irradiated onto the bottom 25b is transmitted in the embedded oxide layer with a transmittance of approximately 100%.

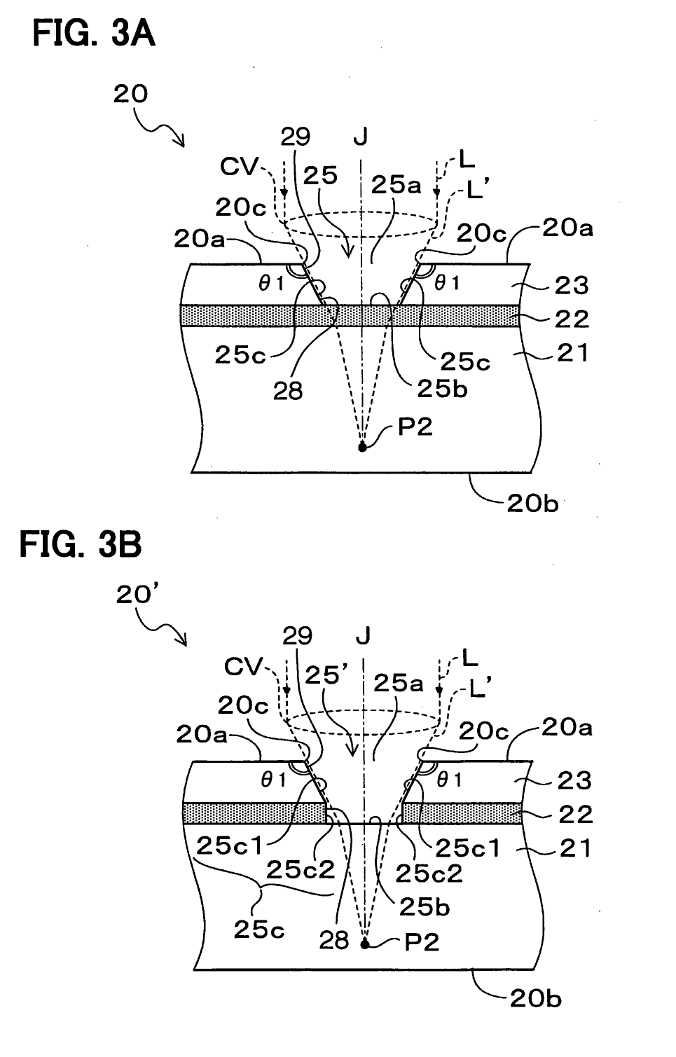

In one embodiment, when the focal point P2 is located at a deep position of the semiconductor substrate 21 (i.e., adjacent the reverse side 20b) with the condenser lens disposed closer to the surface 20a, a laser beam diameter W2 is set to be smaller than a scribe width W1 (i.e., the width of the bottom end 28 of the scribe groove 25). Moreover, as shown in FIG. 3A, the side wall 25c of the scribe groove 25 is approximately parallel to the fringe contour line of the laser beam focused by the condenser lens CV.

In another embodiment shown in FIG. 3B, the depth of the scribe groove 25′ is such that the scribe groove 25′ extends into and through the embedded oxide layer 22 in addition to the single-crystal silicon layer 23. In other words, the formation member in which the scribe groove 25′ is provided is the embedded oxide layer 22 and the single-crystal silicon layer 23. More specifically, the bottom 25b of the scribe groove 25 reaches the semiconductor substrate 21.

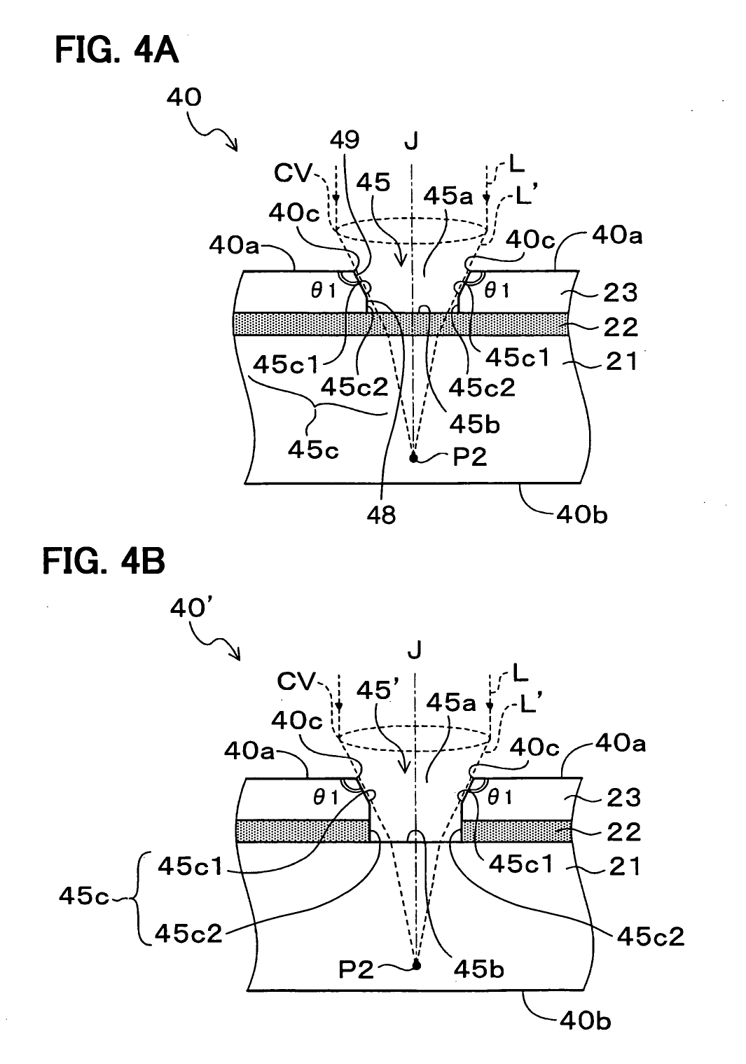

Furthermore, in an embodiment illustrated in FIGS. 3B, 4A, and 4B, only a portion of the side walls 25c, 45c of the scribe groove 25′, 45, 45′ are formed at an obtuse angle. Another portion of the side walls 25c, 45c are formed approximately perpendicular to the outer surface 20a, 40a.

More specifically, in the embodiment of FIG. 3B, the scribe groove 25′ is constructed by forming an opening-side wall 25c1 in the layer 23 and a bottom-side wall 25c2 in the embedded oxide layer 22. The width of the bottom end 28 of the scribe groove 25′ remains approximately constant through the embedded oxide layer 22. As such, since the embedded oxide layer 22 is removed in an irradiation range of the laser beams L1, L2, the embedded oxide layer 22 is unlikely to effect the location of the focal points P1, P2.

Furthermore, since the tilt angle 01 of the opening-side wall 25c1 is similar to the tilt angle θ1 of the scribe groove 25 shown in FIG. 3A, it is possible to make the wall surface of the opening-side wall 25c1 and the fringe contour lines of the laser beams L1, L2 focused by the condenser lens approximately parallel to each other.

In the embodiment of FIG. 4A, the wafer 40 includes the scribe groove 45 extending through the single-crystal layer 23 only. The side walls 45c of the scribe groove 45 includes an opening-side wall 45c1 formed at an obtuse angle (i.e., a slope angle θ1) as described above. The side walls 45c also include a bottom-side wall 45c2 that is substantially perpendicular to the outer surface 40a. As such, the width of the bottom end 48 of the scribe groove 45 remains approximately constant. Since the tilt angle θ1 of the opening-side wall 45c1 is set up in the same manner as the tilt angle θ1 of the scribe groove 25 shown in FIG. 3A, the wall surface of the opening-side wall 45c1 and the fringe contour line of the laser beams L1, L2 focused by the condenser lens can be approximately parallel to each other. In one embodiment, the side walls 45c are formed via dry etching processes. Furthermore, in one embodiment, the opening-side walls 45c1 and the bottom-side walls 45c2 are formed at the same time to thereby facilitate manufacturing.

In the embodiment of FIG. 4B, the scribe groove 45′ has a depth that extends into and through the embedded oxide layer 22 in addition to the single-crystal silicon layer 23. Also, the side walls 45c of the scribe groove 45′ includes an opening-side wall 45c1 formed at an obtuse angle (i.e., a slope angle θ1) as described above. The side walls 45c also include a bottom-side wall 45c2 that is substantially perpendicular to the outer surface 40a. As such, the width of the bottom end 48 of the scribe groove 45′ remains approximately constant. The opening-side wall 45c1 is included in the single-crystal silicon layer 23, and the bottom-side wall 45c2 is included in the single-crystal silicon layer 23 and the oxide layer 22. As such, the embedded oxide layer 22 is removed within an irradiation range of the laser beams L1, L2, for improved control of the location of the focal points P1, P2.

Thus, in the embodiments of FIGS. 1-4B, since the angle part that forms the scribe groove 25 (45) of the chip obtained by dicing the wafer 20, 40 also has an obtuse angle, the angle part is unlikely to chip off as compared with the case where 25 the angle part is at a right angle or an acute angle. Therefore, the chips diced from the wafer 20 (40) are less likely to be degraded in quality.

Moreover, the fringe contour line of the laser beams L1, L2 focused by the condenser lens can be made approximately parallel to the wall surface of the wall 25c, 45c even if the condenser lens is brought close to the surface 20a (40a) of the wafer 20 (40). Thus, the single-crystal silicon layer 23 is unlikely to hinder the focused laser beams L1, L2 from propagating and the focal point P2 can be formed at a deep position of the semiconductor substrate 21.

In the embodiments of FIGS. 3B and 4B, the scribe groove 25, 45 is formed in the embedded oxide layer 22 and the single-crystal layer 33. As such, the oxide layer 22 is unlikely to detrimentally effect the location of the focal points P1, P2.

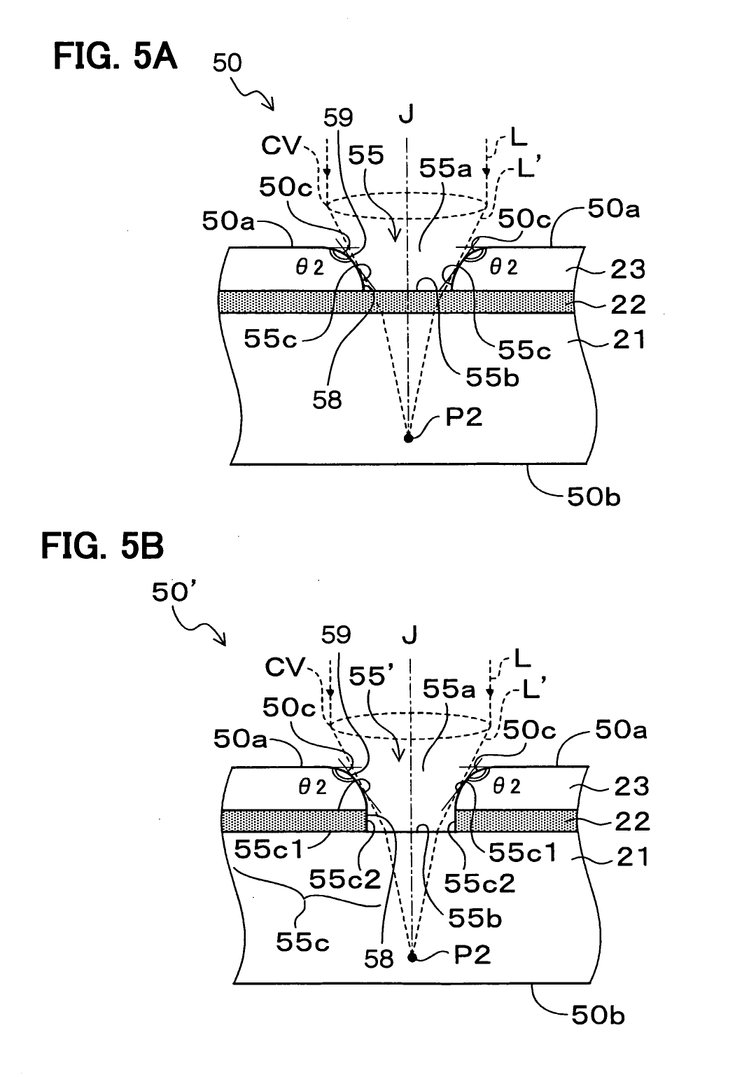

Referring now to FIGS. 5A and 5B, another embodiment is shown. In a wafer 50 according to this embodiment, the side walls 55c is non-planar and curved. However, an angle θ2 is defined between the outer surface 50a and a line tangent to the respective side wall 55c is an obtuse angle as described above.

As shown in FIG. 5A, the wafer 50 is a multilayer substrate of an SOI structure composed of, for example, the semiconductor substrate 21, the embedded oxide layer 22, and the single-crystal silicon layer 23, as in the case of the above-mentioned wafer 20. In the wafer 50, a plurality of chips that underwent an unillustrated diffusion process and the like are aligned and arranged. As in the case of the wafer 20 shown in FIG. 20, there exists a virtual predetermined dicing line DL in the wafer. Moreover, expand tape (not shown) is glued on nearly the whole surface of a reverse side 50b of the wafer 50.

A scribe groove 55 formed in the wafer 50 is also included. The scribe groove 55 is a linear long groove formed along the predetermined dicing line DL, having a sufficient depth to reach the embedded oxide layer 22. The width of the scribe groove 55 at an open end 59 is greater than a width of the scribe groove 55 at a bottom end 58. With this formation, the wall 55c that joins the opening of the scribe groove 55 to the bottom 55b of the scribe groove 55 has a curved shape such that “R-chamfering” is processed on an angle part 50c of the surface 50a of the wafer 50. This scribe groove 55 is formed, in one embodiment, by chemical processing using wet etching, dry etching, by mechanical processing by cutting with a dicing blade, etc., or irradiation of the laser beam. Moreover, the bottom 55b thereof is formed to be such a flat smooth surface as generates neither reflection nor scattering of the laser beams L1, L2.

With this formation, since the tangent angle θ2 that the tangent line of the wall 55c makes with the surface 50a of the predetermined dicing line DL can be made to be an obtuse angle, the angle part 50c can be rounded. Since the angle part that forms the scribe groove 55 of the chip obtained by dicing it from the wafer 50 is also rounded, the angle part is more resistant to chipping as compared with the case where the angle part is of a right angle or acute angle.

In the embodiment shown in FIG. 5B, the scribe groove 55′ is similar to the embodiment of FIG. 5A. However, the depth of the scribe groove 55′ extends through both the single-crystal silicon layer 23 and the embedded oxide layer 22. As such, the side wall 55c includes an opening-side wall 55c1 in the single-crystal silicon layer 23, which is curved as described above. The side wall 55c also includes a bottom-side wall 55c2 in the oxide layer 22, which is planar and approximately perpendicular to the outer surface 50a. As such, the width of the scribe groove 55′ remains constant at the bottom end 58. Accordingly, since the embedded oxide layer 22 is removed within an irradiation range of the laser beams L1, L2, the embedded layer 22 is unlikely to detrimentally effect the location of the focal points P1, P2.

Thus, since the angle part that forms the scribe groove 55 of the chip obtained by dicing it from the wafer 50 is also rounded, the angle part is resistant to chipping. Therefore, since the angle part is unlikely to chip off even if the chips rub against each other, the wafer 50 can reduce degradation in quality of the chips diced therefrom.

In the each embodiment described above, the embedded oxide layer and the single-crystal silicon layer are exemplified as the formation layer on the wafer located adjacent the surface of the predetermined position onto which the laser beam is irradiated. However, it will be appreciated that these layers could be otherwise embodied.

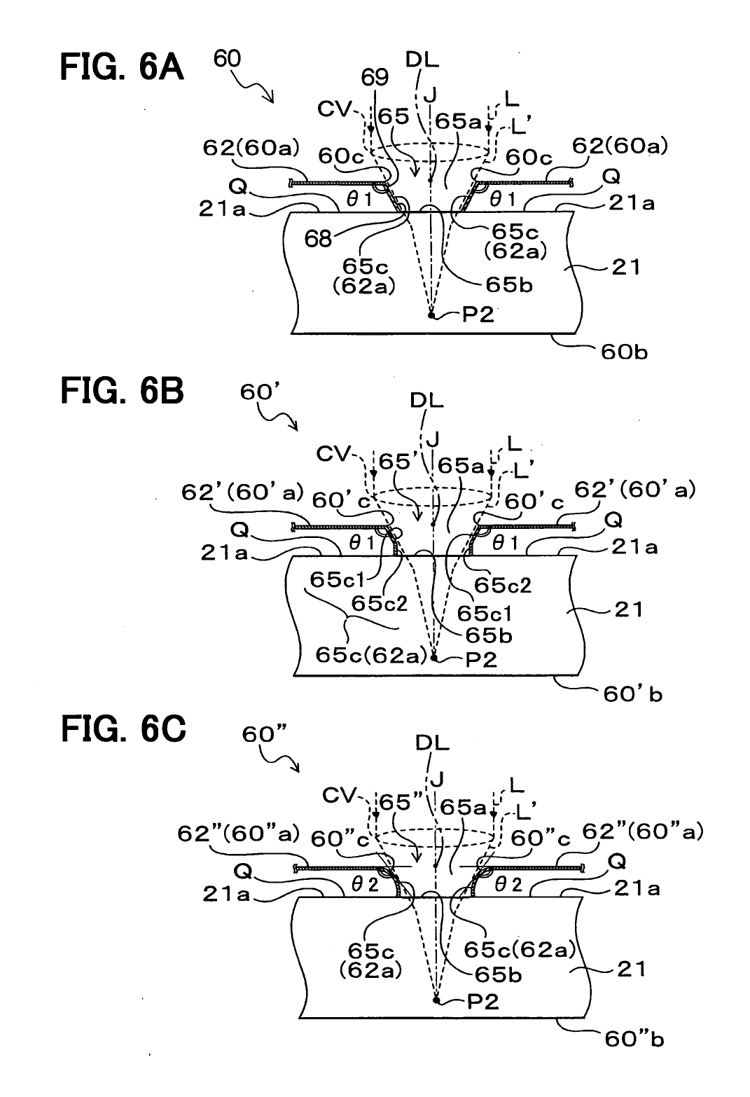

Referring for instance to FIGS. 6A through 6C, another embodiment is shown. In this embodiment, the formation member in which the scribe groove 65, 65′, 65″ is provided is a cap or cover that protects a part of the semiconductor substrate (i.e., a formation layer on the wafer). The scribe groove 65 of FIG. 6A generally corresponds in shape to that of FIGS. 1 through 3A. The scribe groove 65′ of FIG. 6B generally corresponds in shape to that of FIGS. 3B through 4B. The scribe groove 65″ of FIG. 6C generally corresponds in shape to that of FIGS. 5A and 5B.

As shown in FIG. 6A, in the case of a wafer 60, a cap (i.e., cover) 62 is included as a box-like layer with a frustoconic cross sectional shape. In one embodiment, the cap 62 is made up of silicon, resin, glass, etc. The cap 62 protects a surface 21 a of the semiconductor substrate 21 by covering a portion Q (i.e., range) thereof.

The scribe groove 65 is included between the caps 62 like this arranged side by side across the predetermined dicing line DL. Each of the caps 62 is formed in such a way that its lateral face 62a becomes a wall 65c that extends from the outer surface 60a to a bottom 65b of the scribe groove 65. The wall 65 makes an obtuse angle θ1 (90°<θ1<180°) with the outer surface 60a of the wafer 60. In FIG. 6A, the reference symbol 60b denotes a reverse side of the wafer 60.

Thus, since the angle part can be made resistant to chipping off as compared with the case where the angle part (angle part of the cap 62) is of a right angle or acute angle, the angle part (angle part of the cap 62) is unlikely to chip off even if the chips like this rub against each other. Accordingly, degradation in quality of the chip is less likely.

As shown in FIG. 6B, the cap (or cover) 62′ includes the groove 65′. The groove 65′ includes a side wall 65c composed of an opening-side wall 65c1 that is provided at an obtuse angle θ1 with respect to the outer surface 60′a and a bottom-side wall 65c2 that is substantially perpendicular to the outer surface 60′a. As such, the angle part (angle part of the cap 62′) is less resistant to chipping off as compared with the case where the angle part (angle part of the cap 62′) is at a right angle or an acute angle. Therefore, the angle part (angle part of the cap 62′) is unlikely to chip off even if the chips rub against each other. Accordingly, the wafer 60′ that can reduce degradation in quality of the chip diced therefrom.

Moreover, as shown in FIG. 6C, the wafer 60″ includes the scribe groove 65″ in the cap (or cover) 62″. The scribe groove 65″ is formed to be a curved shape with “R-chamfering” processed on the angle part 60c of the above-mentioned cap 62. Thus, an obtuse angle θ2 is defined between a line tangent to the side wall 65c and the outer surface 60″a.

Thus, the angle part of the cap 62″ is unlikely to chip off even if the chips like this rub against each other. Therefore, degradation in quality of the chip can be reduced.

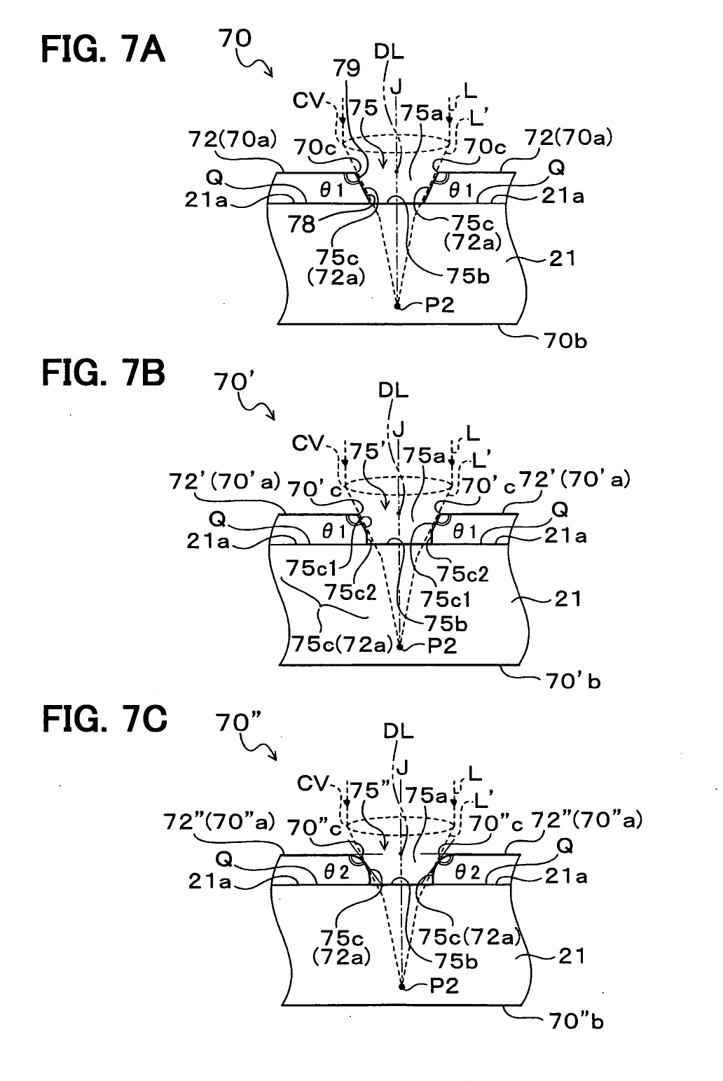

Furthermore, as shown in the embodiments of FIGS. 7A to 7C, a passivation film 72 that can be included as the formation member for the scribe groove 75, 75′, 75″. The scribe groove 75 of FIG. 7A generally corresponds in shape to that of FIGS. 1 through 3A. The scribe groove 75′ of FIG. 7B generally corresponds in shape to that of FIGS. 3B through 4B. The scribe groove 75″ of FIG. 7C generally corresponds in shape to that of FIGS. 5A and 5B.

As shown in FIG. 7A, in the case of a wafer 70, a passivation film 72 (SiO2, SiN, etc.) that protects a part of the surface 21 a of the semiconductor substrate 21 is formed on the surface 21a of the semiconductor substrate 21 so as to cover and protect a portion (range) Q.

An opening 75a between adjacent passivation films 72 functions as the scribe groove 75. The side wall 75c of the scribe groove 75 is provided at an obtuse angle θ1 (90°<θ1<180°) with respect to an outer surface 70a of the wafer 70. In FIG. 7A, the reference symbol 70b denotes a reverse side of the wafer 70. Thus, the angle part is unlikely to chip off even if the chips like this rub against each other, and degradation in quality of the chip is less likely.

As shown in FIG. 7B, the scribe groove 75′ has a wall 75c composed of an opening-side wall 75c1 that forms the opening side of the wall 75c of the above-mentioned passivation film 72 and a bottom-side wall 75c2 that is approximately perpendicular with the outer surface 70′a. As such, chipping is less likely and chip degradation is less likely.

In the embodiment of FIG. 7C, the scribe groove 75″ is formed in a curved shape such that the angle part 70 of the above-mentioned passivation film 72 is “R-chamfered.” A line tangent to the side wall 75c and the outer surface 70″a is an obtuse angle θ2 (90°<θ2<180°). As such, chipping is less likely and chip degradation is less likely.

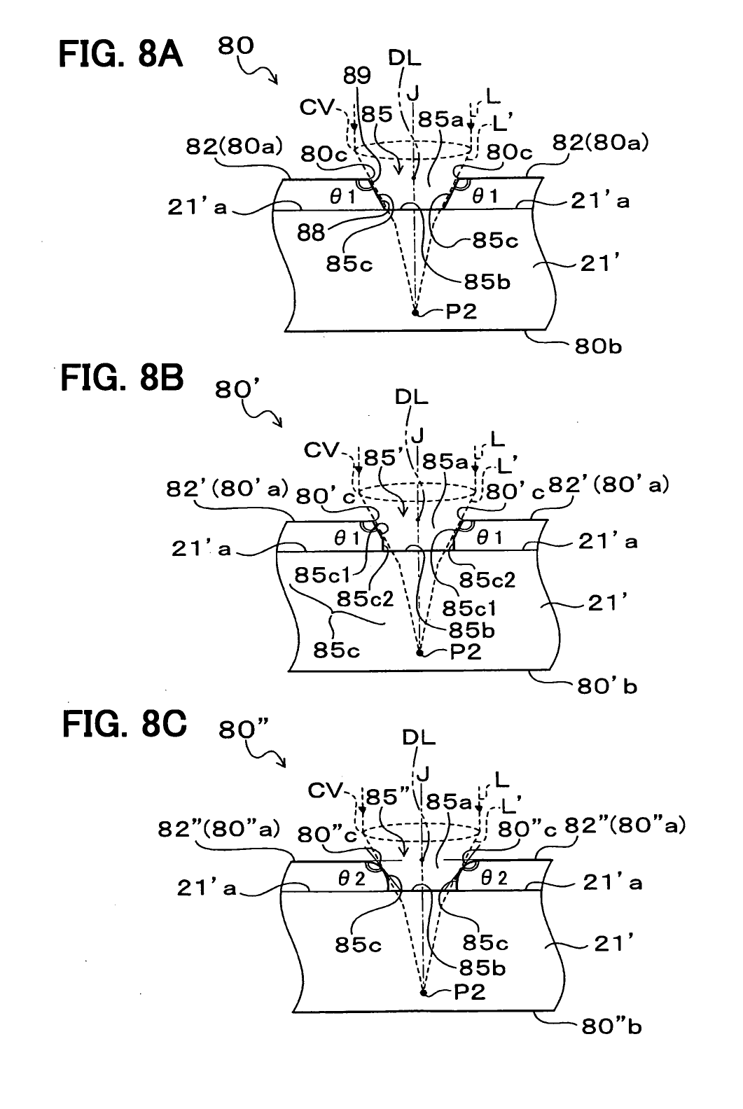

Moreover, the formation member for the scribe groove may be a part of a heterojunction structure that forms a heterojunction in conjunction with the semiconductor substrate (i.e., a formation member on the wafer) as shown in the embodiments of FIGS. 8A to 8C. A scribe groove 85, 85′, 85″ is formed in the heterojunction structure in each embodiment. The scribe groove 85 of FIG. 8A generally corresponds in shape to that of FIGS. 1 through 3A. The scribe groove 85′ of FIG. 8B generally corresponds in shape to that of FIGS. 3B through 4B. The scribe groove 85″ of FIG. 8C generally corresponds in shape to that of FIGS. 5A and 5B.

As shown in FIG. 8A, in the case of a wafer 80, a silicon layer 82 that creates a heterojunction structure in conjunction with a surface 21′a of a substrate 21′ made up of a compound semiconductor (GaN, SiC, etc.) is formed on the surface 21′a of the substrate 21′. An opening 85a between adjacent silicon layers 82 defines the scribe groove 85. The side wall 85c of the scribe groove 85 is at an obtuse angle θ1 (90°<θ1<180°) with an outer surface 80a of the wafer 80. As such, chipping is less likely and chip degradation is less likely.

Moreover, in the embodiment shown in FIG. 8B, the side wall 85c of the scribe groove 85′ includes an opening-side wall 85c1 at an obtuse angle and a bottom-side wall 85c2 that is approximately parallel to the outer surface 80′a. As such, chipping is less likely and chip degradation is less likely.

Furthermore, as shown in FIG. 8C, the side wall 85c of the scribe groove 85″ is curved. A line tangent with the side wall 85c forms an obtuse angle with the outer surface 80″a. As such, chipping is less likely and chip degradation is less likely.

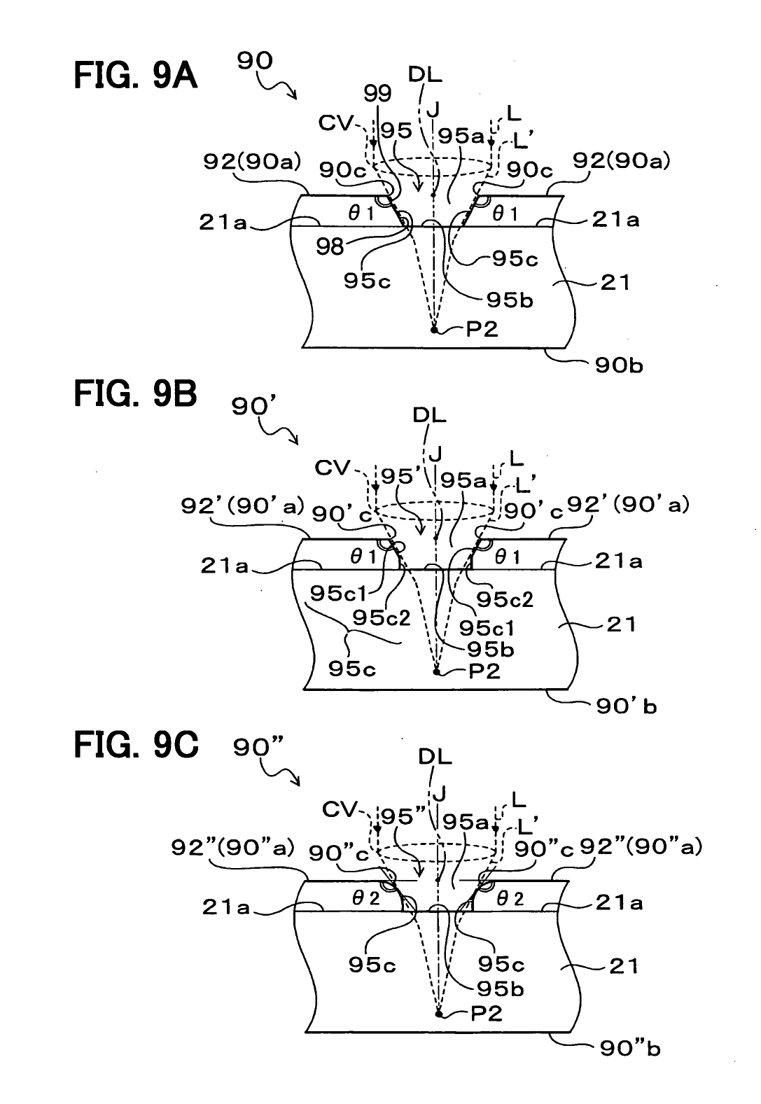

In another embodiment illustrated in FIGS. 9A through 9C, the formation member for the scribe groove is an aluminum electrode pad formed on the semiconductor substrate. The aluminum electrode pad 92, 92′, 92″ is formed on the surface 21 a of the substrate. The scribe groove 95 of FIG. 9A generally corresponds in shape to that of FIGS. 1 through 3A. The scribe groove 95′ of FIG. 9B generally corresponds in shape to that of FIGS. 3B through 4B. The scribe groove 95″ of FIG. 9C generally corresponds in shape to that of FIGS. 5A and 5B. As such, chipping is less likely and chip degradation is less likely.

Several of the above-mentioned embodiments include a multilayer substrate of an SOI structure composed of a semiconductor substrate, an embedded oxide layer, and a single-crystal silicon layer as a semiconductor wafer. However, the SOI structure may be replaced with a SIMOX (Silicon, IMplanted OXide), and a semiconductor material may be SiC, ZnO, AIN, GaAs, or the like, for example. The adoption of these modifications gives the same action and effects as described above.

Furthermore, the semiconductor wafer according to this invention can be applied to the case where a workpiece that is formed by MEMS (Micro Electro Mechanical Systems), for example, an acceleration sensor, a gyrosensor, an image sensor, etc. are constructed on the semiconductor wafer, and such applications can attain the same action and effects as the embodiments described above.

While only the selected embodiments have been chosen to illustrate the present invention, it will be apparent to those skilled in the art that various changes and modifications can be made therein without departing from the scope of the disclosure as defined in the appended claims. Furthermore, the foregoing description of the embodiments herein is provided for illustration only, and not for the purpose of limiting the disclosure as defined by the appended claims and their equivalents.

What is claimed is:

1. A semiconductor wafer for which irradiation of a laser beam forms a modified region due to multiphoton absorption to thereby facilitate dicing of the semiconductor wafer, the semiconductor wafer comprising:
a formation member with an outer surface; and
a scribe groove located on the formation member according to an irradiation position of the laser beam, the scribe groove including a side wall that is planar and that is provided at a tilt angle with respect to the outer surface of the formation member,
wherein the tilt angle is the smallest angle between the side wall and the outer surface, and wherein the tilt angle is between ninety degrees (90°) and one hundred eighty degrees (180°).

2. A semiconductor wafer for which irradiation of a laser beam forms a modified region due to multiphoton absorption to thereby facilitate dicing of the semiconductor wafer, the semiconductor wafer comprising:
a formation member with an outer surface; and
a scribe groove located on the formation member according to an irradiation position of the laser beam, the scribe groove including a side wall that is curved such that a tangent angle is defined between a tangent line of the side wall and the outer surface of the formation member,
wherein the tangent angle is the smallest angle between the tangent line and the outer surface, and wherein the tangent angle is between ninety degrees (90°) and one hundred eighty degrees (180°).

3. A semiconductor wafer for which irradiation of a laser beam forms a modified region due to multiphoton absorption to thereby facilitate dicing of the semiconductor wafer, the semiconductor wafer comprising:
a formation member; and
a scribe groove located on the formation member according to an irradiation position of the laser beam, the scribe groove defining an open end and a bottom end,
wherein a width of the scribe groove is greater at the open end than at the bottom end.

4. The semiconductor wafer of claim 3, wherein the formation member includes an outer surface,
wherein the scribe groove includes a side wall that is planar and that is provided at a tilt angle with respect to the outer surface of the formation member,
and wherein the tilt angle is the smallest angle between the side wall and the outer surface, and wherein the tilt angle is between ninety degrees (90°) and one hundred eighty degrees (180°).

5. The semiconductor wafer of claim 3, wherein the formation member includes an outer surface,
wherein the scribe groove includes a side wall that is curved such that a tangent angle is defined between a tangent line of the side wall and the outer surface of the formation member,
and wherein the tangent angle is the smallest angle between the tangent line and the outer surface, and wherein the tangent angle is between ninety degrees (90°) and one hundred eighty degrees (180°).

6. The semiconductor wafer of claim 3, wherein the formation member is an outer layer and an embedded layer such that the depth of the scribe groove extends into the outer layer and the embedded layer.

7. The semiconductor wafer of claim 3, wherein the formation member includes an outer surface,
wherein the scribe groove includes a side wall that includes an opening-side wall adjacent the open end and a bottom-side wall adjacent the bottom end,
wherein the open-side wall is planar and provided at a tilt angle with respect to the outer surface of the formation member,
wherein the tilt angle is the smallest angle between the opening-side wall and the outer surface, wherein the tilt angle is between ninety degrees (90°) and one hundred eighty degrees (180°), and
wherein the bottom-side wall is approximately perpendicular to the outer surface of the formation member.

8. The semiconductor wafer of claim 3, wherein the formation member includes an outer surface,
wherein the scribe groove includes a side wall that includes an opening-side wall adjacent the open end and a bottom-side wall adjacent the bottom end,
wherein the open-side wall is curved such that a tangent angle is defined between a tangent line of the open-side wall and the outer surface of the formation member,
wherein the tangent angle is the smallest angle between the tangent line and the outer surface, wherein the tangent angle is between ninety degrees (90°) and one hundred eighty degrees (180°), and
wherein the bottom-side wall is approximately perpendicular to the outer surface of the formation member.

9. The semiconductor wafer of claim 3, wherein the formation member is a member chosen from a group consisting of a cap that protects a substrate of the semiconductor wafer, a passivation film, a heterojunction structure, and an electrode pad.

10. The semiconductor wafer of claim 3, wherein the width of the scribe groove at the bottom end is greater than a diameter of the laser beam.

11. The semiconductor wafer of claim 4, wherein the laser beam is focused according to a convergence angle, and wherein the tilt angle is approximately equal to half of the convergence angle plus ninety degrees (90°).

12. The semiconductor wafer of claim 5, wherein the tangent angle is approximately equal to half of the convergence angle plus ninety degrees (90°).
